(19) United States
(12) Patent Application Publication
(10) Pub. No.: US 2005/0236028 A1
(43) Pub. Date: Oct. 27, 2005

(54) Heat to cooling converter

(76) Inventor: Richard J. Strnad, Plano, TX (US)

Correspondence Address: Richard J. Strnad, 2524 Preston Rd., #204, Plano, TX, 75093, US

(21) Appl. No.: 10/992,026

(22) Filed: Nov. 18, 2004

Related U.S. Application Data
(60) Provisional application No. 60/523,278, filed on Nov. 18, 2003.

(51) Int. Cl. H01L 35/34; F25J 3/00; H01L 37/00; F25B 21/02; H01L 35/28

(52) U.S. Cl. 136/201; 136/204; 62/3.2

(57) ABSTRACT

The present invention is embodied in a pair of electrically connected energy conversion devices. One device, converting thermal energy to electric energy is electrically connected to the second thermally isolated device which is converting electric energy to cooling. Thermal isolation is achieved by using an electrically conducting adiabatic wall which is maintained at constant temperature. The constant temperature of the wall is maintained by removing excessive heat by conduction, convection, or radiation.

This application relates to Provisional Patent Application No. 60/523,278 titled Thermoelectric Heat Exchanger filed on Nov. 18, 2003

### FIELD OF THE INVENTION

This invention relates to cooling apparatus, and methods for making same. More particularly, the invention is directed to thermoelectric, tunneling or displacement current based electricity generators and sub-ambient cooling devices, attaining high relative efficiency through the use of an electrically conductive adiabatic wall which is disseminating excessive heat.

### RELATED ART

“Heating” and “cooling” are terms used to describe the absorption and emission of heat from a substance. When a substance is absorbing thermal energy it is heated and when a substance is expelling thermal energy it is cooled. The heat removing process or cooling is called an exothermic event and the heat absorbing process is called an endothermic event. Heating is relatively easy to achieve, cooling is more difficult.

Cooling is conventionally accomplished through gas-liquid compression cycles using fluid type refrigerants to implement the heat transfer. Such systems are used extensively for cooling homes, transportation vehicles, perishable items or electromechanical systems. Although these systems are well established, a new cooling system presented in this application offers a viable replacement. A unique concept integrates the Seebeck and Peltier devices into one and converts heat energy directly to cooling.

Thermoelectric energy conversion is the interconversion of thermal and electrical energy for power generation and cooling and is based on the Seebeck and Peltier effects. More recently, some scientists have attempted to put to use the avalanche breakdown effect, the tunneling effect, and the Fowler-Nordheim tunneling thermionic effect to increase conversion efficiency by introducing virtual electrical gaps and mechanical microgaps between the p- and n-type semiconductor regions. In the early 1950's, progress in solid-state physics and chemistry led to the development of semiconductor thermoelements with the result that reasonably efficient thermoelectric devices could be constructed. Metallic thermoelectric devices provide only very low efficiencies, the most favorable being combinations of bismuth and antimony, which provide efficiencies of ca 1%, selected semiconductors can provide efficiencies of ca 8-10%.

The technique of direct energy conversion is characterized by the absence of moving parts, high reliability, quietness, lack of vibration, low maintenance and absence of pollution problems. Thermoelectric generators have been used increasingly in specialized applications in which combinations of their desirable features outweigh their high cost and low generating efficiencies, which are typically ca 3-7%. Large scale thermoelectric generators cannot compete with oil-fired central power stations, which operate at efficiencies of 35-40%. The most advanced thermoelectric systems are the radioisotope thermoelectric generators (RTGs), which have been developed for military and commercial systems under the aegis of DOE. Other thermoelectric generators were employed in space, in floating and terrestrial weather stations, cardiac pacemakers, and navigational buoys. Some other applications include power generation in remote navigational lights, communication line repeaters, and cathodic protection, eg. protection of the east-west pipeline across Saudi Arabia by 34 thermoelectric stations.

Thermoelectric cooling, like thermoelectric power generation, has had increased applications in those areas where the advantages of the thermoelectric conversion process, ie, small space, light weight, high reliability, no noise or pollution can be utilized. Thermoelectric cooling devices have been developed for a variety of military and commercial applications. These include submarine air-conditioning systems, small refrigerators and recreational cooler chests, cooling of electronic components, laboratory instruments, and cooling for electro-optical systems. The state of the art is characterized by individual couples having pumping capacities of 1-4 W.

The conversion efficiency of a thermoelectric generator and the coefficient of performance of a thermoelectric refrigerator depends upon the properties of the technologies are established; these are bismuth telluride, lead telluride, and the Si—Ge thermoelectric materials as expressed by their figure of merit. To date, three material alloys. The development of solid state materials with enhanced figures of merit is in progress. Therefore, thermoelectric energy conversion provides a unique solid state technology that complements rather than replaces existing technologies.

Thermionic energy conversion method involves heat energy conversion to electric energy by thermionic emission. In this process, electrons are thermionically emitted from the surface of a metal by heating the metal. Thermionic conversion does not require an intermediate form of energy or a working fluid, other than electric charges, in order to change heat into electricity. Thermionic energy conversion is based on the concept that a low electron work function cathode in contact with a heat source will emit electron. These electrons are absorbed by a cold, high work function cathode and they can flow back to the cathode through an external load where they perform useful work. From a physics standpoint, thermoelectric devices are similar to thermionic devices. In both cases a temperature gradient is placed upon a metal or semiconductor, and both cases are based upon the concept that electron motion is electricity. However, the electron motion also carries energy. In order to increase the power density, Kucherov describes in US Patent No.: U.S. Pat. No. 6,396,191 B1 a thermionic semiconductor diodes with a gap between the n and p or metallic regions which enhances performance.

Energy conversion technique, U.S. Pat. No. 6,281,514 B1 described by Tafkhelidze, is related and is involving tunneling of electrons. In closely spaced materials electrons can tunnel from material to the next, carrying their heat with them. With the addition of a voltage bias, which helps keep the electrons flowing in one direction, the heat is then transferred from one side to the other. Because the two sides are separated by a gap the heat cannot easily flow back. The claimed efficiency is in excess of 55% of Carnot efficiency, compared to 5-8% for thermoelectrics.

### SUMMARY OF THE INVENTION

The present invention combines electricity generating device and cooling device into one. A pair of thermoelectric pellets, one of P or N-type generates Seebeck electricity, second one N or P type is used to generate Peltier cooling.

The present application discloses a new type of cooling device which converts thermal energy directly to cooling. The electricity generator and the cooling device are separated by an adiabatic wall and both devices are in thermal equilibrium with each other. The adiabatic wall also provides electrical connection between the two devices. The small distance between both devices is minimizing the electrical resistance thus guaranteeing maximum power transfer from device to device.

The inventor recognizes that the unique structure of the device does not require both devices to be made of same material when thermoelectric materials are involved. For example, one device can be made of P or N type lead telluride or Si—Ge alloy, while the second device can be made of P or N type bismuth telluride. This arrangement will be better suited in applications, where higher temperatures are involved and which exceed the safe operating temperature of bismuth telluride.

A further object of the present invention is to remove excessive heat generated by both devices. The heat removal is accomplished through the adiabatic plane. Circulating fluid or gas in hollow plane must remove unwanted heat and provides critical function in the operation of the device.

A further object of the invention is to design the adiabatic wall with smallest electrical resistance and highest heat removal effectiveness. Low electrical resistance is essential to minimize energy transport losses and the contact area of the adiabatic wall with the fluid or gas must be optimized for maximum heat extraction.

These and other features of the invention will be more clearly understood and appreciated upon considering the detailed embodiments described hereinafter.

### BRIEF DESCRIPTION OF THE DRAWINGS

These and other aspects, features and advantages, the sophistication, as well as methods, operation, functions and related elements of structure, and significance of the present invention will become apparent in light of the following detailed description of the invention and claims, as illustrated in the accompanying drawings.

FIG. 1 is a drawing of an n-type Seebeck device functioning as an electricity generator;

FIG. 2 is a drawing of a p-type Sebeck device functioning as an electricity generator;

FIG. 3 is a drawing of an n-type Peltier device functioning as a cooling and heating device;

FIG. 4 is a drawing of a p-type Peltier device functioning as a cooling and heating device;

FIG. 5 is a schematic drawing of the electrical circuit with Seebeck device associated with a power meter;

FIG. 6 is a schematic drawing of the electrical circuit with Peltier device associated with a battery;

FIG. 7 is a schematic diagram of the electrical circuit associated with combination of Seebeck and Peltier device;

FIG. 8 is a cross section view of the Heat to Cooling Converter showing the diathermic plane;

FIG. 9 is an isometric drawing of the Heat to Cooling Converter showing the flow of applied heat and the flow of the absorbed heat.

### DETAILED DESCRIPTION OF THE INVENTION

In the following description of the invention or preferred embodiments, reference is made to the accompanying drawings which form a part hereof, and in which is shown by way of illustration specific embodiments in which the invention may be practiced. These embodiments are described in sufficient detail to enable those skilled in the art to practice the invention, and it is to be understood that other embodiments may be utilized and that logical, mechanical and electrical changes may be made without departing from the spirit of scope of the invention. To avoid detail not necessary to enable those skilled in the art to practice the invention, the description may omit certain information known to those skilled in the art. The following detailed description is, therefore, not to be taken in a limiting sense, and the scope of the present invention is defined only by the appended claims.

The conceptual ground work for the present invention involves using adiabatic wall with Seebeck and Peltier type devices. In this manner, the adiabatic wall provides for both devices to coexist in thermal independent equilibrium states for any temperatures involved and with the common adiabatic wall maintained at constant temperature by induced heat removal with heat sinks, flowing gas, fluid or by alternative means, such as solid state, plasma or active refrigerants. The second function of the adiabatic wall is to provide good electrical connection between electricity producing Seebeck device and the cooling element, the Peltier cell.

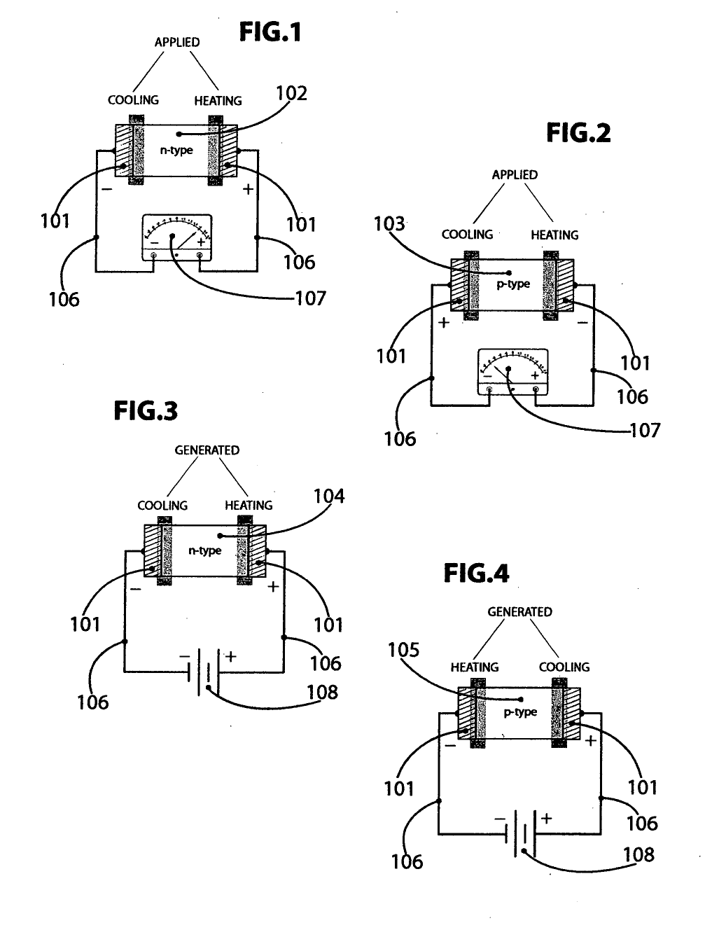

Referring now to prior art FIG. 1, the principle of operation of Seebeck device is shown. Reference numerals used in FIG. 1 which are like, similar or identical to reference numerals used in remaining figures. Thermoelectric electricity generator based on Seebeck effect and shown in FIG. 1 consists of thermoelectric n-type material 102. Each end of the semiconductor material is connected to the circuits with two metal contacts 101. Two wires 106 connect device to power indicator 107. Thermal gradient of defined direction applied across the device will produce voltage polarity indicated in 107. In FIG. 2 is shown thermoelectric material of p-type 103. With identical thermal polarity gradient applied to the device in FIG. 2, indicator 107 shows the voltage polarity reversed, when referenced to FIG. 1. The prior art Peltier effect cooling principle is shown in FIGS. 3 & 4. In FIG. 3 is shown a Seebeck device with n-type thermoelectric material 104. Contacts 101 are used to connect wires 106 to voltage source 108. For given voltage polarity and n-type material, resulting cooling and heating effect is shown. In FIG. 4 is shown identical arrangement to FIG. 3 however the semiconductor material is of p-type 105 and the resulting cooling and heating effects are of opposite direction.

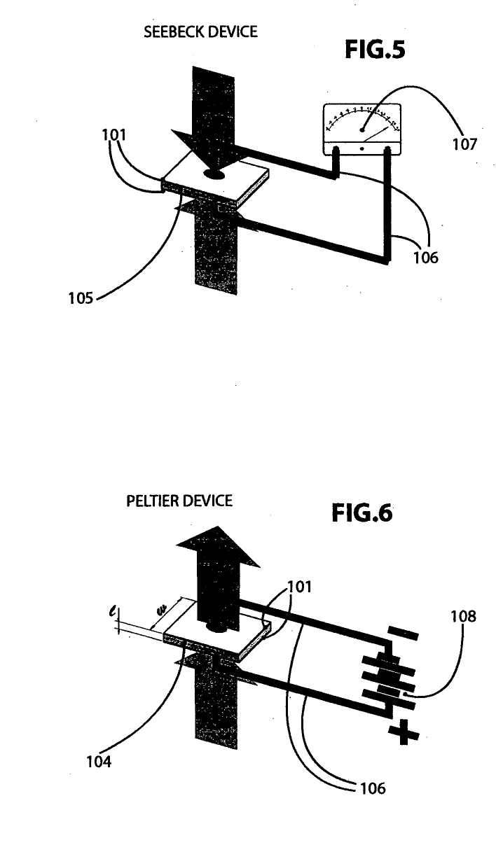

Referring now to FIG. 5, a circuit diagram is showing a Seebeck device connected with wires 106 to a power indicator 107 and in FIG. 6 is shown complementary Peltier device connected with wires 106 to battery 108. The two devices shown in FIGS. 5 & 6 are connected together and this is shown in FIG. 7. Thermal gradient applied across the Seebeck device generates electromotive force which is applied to the Peltier cooling device below. Using available Seebeck and Peltier devices and connecting them in this configuration will result in microscopic cooling result and the practicality is miniscule. Thermoelectric cells produce small voltages and large currents, voltages obtained from average bismuth telluride pellet 1.5×1.5×4.0 mm in size are about 200.0 μV/° C. and with ΔT=100° C., the output per cell would be approximately 20.0 mV with current 1=5.0 Amperes. To transport this voltage and current from Seebeck cell to Peltier cell is impractical if not impossible. In addition, commercial multi pellet devices internally connected in series are comprised of thermoelectric pellets of p and n-type and have build in losses due to parametric variations of the two mentioned materials.

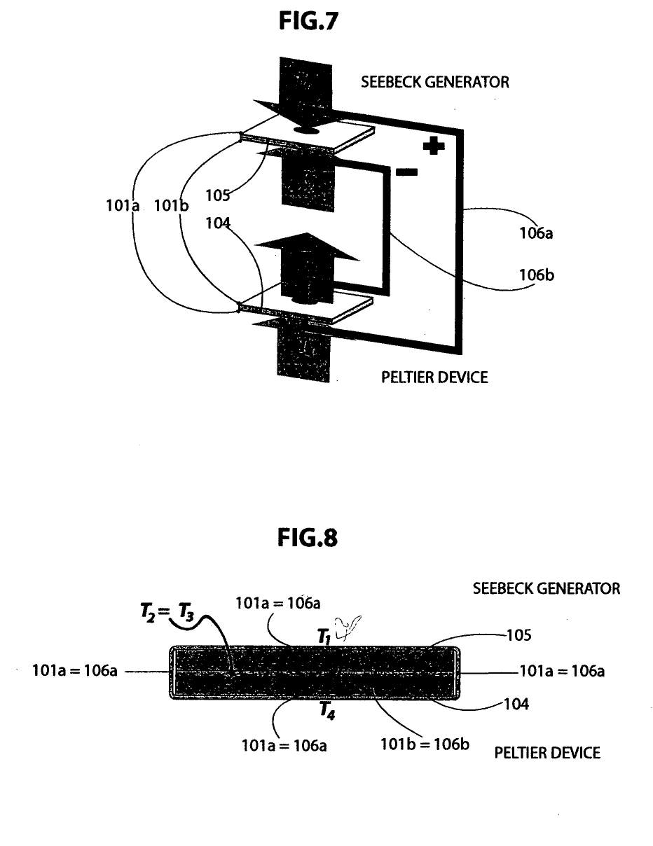

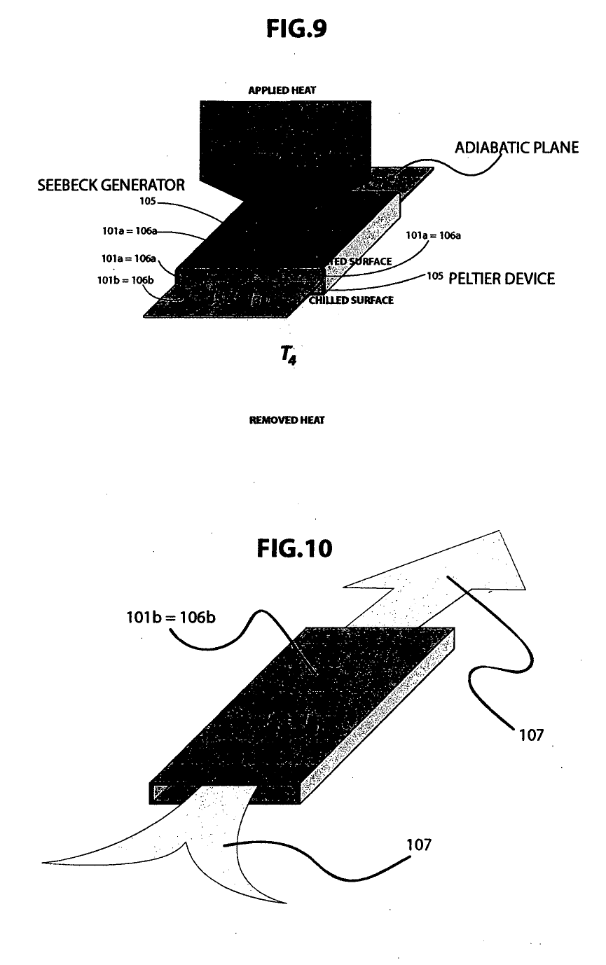

The depiction in FIG. 8 portrays the heart of this invention. By using one common electrode 101b=106b in both devices, the ohmic resistance of this plane is kept at minimum thus minimizing the Joules losses. One polarity current flows through the adiabatic plane 101a =106a from Seebeck cell to Peltier cell and the second, opposite polarity current flows from the Seebeck device to the Peltier device through conductive envelope 101a =106a. The temperature difference ΔT₁=T₁−T₂ applied across the Seebeck cell produces an emf in the thermoelectric material 105 and this emf: is transferred to the Peltier cell thermoelectric material 104 where it generates temperature differential ΔT₂=T₄−T₃ across the Peltier cell and produces desired cooling effect. The type of materials 104 & 105 used in the device must always be of opposite type.

Still further applications are depicted in isometric picture in FIG. 9. Adiabatic nature of the middle electrode 101b=106b is encompassed by constantly removing excessive heat at both ends by convection of conduction. The temperature of the adiabatic element is maintained constant and T₂=T₃. To enhance performance of the Heat to Cooling Converter, the adiabatic plane may be made hollow and cooling fluid or cold pressurized gas 107 may be used for cooling, as illustrated in FIG. 10.

It will be understood by those skilled in the art that the embodiments set forth hereinbefore are merely exemplary of the numerous arrangements for which the invention may be practiced, and as such may be replaced by equivalents without departing from the invention which will now be defined by appended claims.

Although an embodiment of the present invention has been shown and described in detail herein, along with certain variants thereof many other varied embodiments that incorporate the teachings of the invention may be easily constructed by those skilled in the art. Accordingly, the present invention is not intended to be limited to the specific form set forth herein, but on the contrary, it is intended to cover such alternatives, modifications, and equivalents, as can be reasonably included within the spirit and scope of the invention.

1. A heat to cooling converter comprising:
a Seebeck type emf generator situated to be connected to said adiabatic plane;
an adiabatic plane absorbing heat from the Seebeck generator and transferring emf generated by the Seebeck generator to Peltier device;
a Peltier type cooling device connected to said adiabatic plane;
an adiabatic plane absorsing heat from the Peltier generator and supplying power to the Peltier generator.

2. The converter of claim 1 further comprising a solid adiabatic plane expelling undesired heat.

3. The converter of claim 2 with hollow adiabatic plane expelling undesired heat through passing gas or liquid.

4. The converter of claim 1 wherein said thermoelectric material forming Seebeck device is of different composition than thermoelectric material used to form the Peltier device.

5. (canceled)

6. (canceled)

7. (canceled)

8. (canceled)

9. (canceled)

10. The converter of claim 1 wherein said cooling device is of thermionic character.

11. A heat to cooling converter comprising:
a pair of thermoelectric materials of metallic nature;
a pair of thermoelectric materials of semiconductive nature;
a pair of thermoelectric materials of semimetallic nature.

12. A heat to cooling converter comprising:
a pair of thermoelectric crystalline materials;
a pair of thermoelectric polycrystalline materials;
a pair of thermoelectric amorphous materials.

13. The converter of claim 12 wherein said crystalline materials are slotted wafers sliced from pulled ingots.

14. (canceled)
